(19) United States
(12) Patent Application Publication
(10) Pub. No.: US 2025/0017064 A1
(43) Pub. Date: Jan. 9, 2025

(54) DISPLAY DEVICE

(71) Applicant: Samsung Display Co., LTD., Yongin-si (KR)

(72) Inventor: KIWOOK KIM, Yongin-si (KR)

(21) Appl. No.: 18/627,935

(22) Filed: Apr. 5, 2024

(30) Foreign Application Priority Data
Jul. 4, 2023 (KR) 10-2023-0086583

(51) Int. Cl. H10K 59/131

(52) U.S. Cl. CPC H10K 59/131

(57) ABSTRACT

A display device includes a substrate including a display area and a peripheral area surrounding the display area. The peripheral area includes a first peripheral area extending in a first direction and a second peripheral area extending in a second direction intersecting the first direction, where a second length of the second peripheral area is longer than a first length of the first peripheral area. The display device includes gate lines disposed in the display area on the substrate and extending in the first direction, main data lines disposed in the display area on the substrate and extending in the first direction, sub data lines disposed in the display area and extending in the second direction, a gate driver corresponding to the gate lines and disposed in the second peripheral area, and a data driver corresponding to the main data lines and disposed in the second peripheral area.

This application claims priority to Korean Patent Application No. 10-2023-0086583, filed on Jul. 4, 2023, and all the benefits accruing therefrom under 35 U.S.C. § 119, the content of which in its entirety is herein incorporated by reference.

### BACKGROUND

### Field

Example implementations of the inventive concept relate generally to a display device. More specifically, example implementations of the inventive concept relate to a display device providing visual information.

### Discussion of the Related Art

As information technology develops, the importance of display devices, which are a connecting medium between users and information, is emerging. Accordingly, the use of display devices such as, for example, liquid crystal display devices, organic light emitting display devices, and plasma display devices is increasing.

In some cases, a display device may display an image with a wide viewing angle, or the viewing angle of the image displayed on the display device may be controlled to improve reflection for security or safety reasons.

### SUMMARY

Embodiments supported by aspects of the present disclosure provide a display device with improved display quality.

A display device according to an embodiment of the present invention may include a substrate including a display area and a peripheral area surrounding the display area. The peripheral area includes a first peripheral area extending in a first direction and a second peripheral area extending in a second direction intersecting the first direction, where a second length of the second peripheral area is longer than a first length of the first peripheral area. The display device includes gate lines disposed in the display area on the substrate and extending in the first direction, main data lines disposed in the display area on the substrate and extending in the first direction, sub data lines disposed in the display area on the substrate and extending in the second direction, a gate driver corresponding to the gate lines and disposed in the second peripheral area on the substrate, and a data driver corresponding to the main data lines and disposed in the second peripheral area on the substrate.

In an embodiment, the main data lines may respectively correspond to the sub data lines and may be electrically connected to the sub data lines.

In an embodiment, the second length may be about three times or more than the first length.

In an embodiment, the display area may include a first display area and a second display area adjacent to each other.

In an embodiment, the display device may further include a first pixel disposed in the first display area on the substrate and including: a first circuit, and a first light emitting device electrically connected to the first circuit and controlled by a first light emission control signal. The display device may include a second pixel disposed in the second display area on the substrate and including: a second circuit, and a second light emitting device electrically connected to the second circuit and controlled by the first light emission control signal. The display device may include a light control pattern disposed on at least one of the first pixel and the second pixel, where the light control pattern blocks at least one of portion of a light emitted from the first pixel and a portion of light emitted from the second pixel.

In an embodiment, the light control pattern may not be disposed on an upper portion of the first pixel and may be disposed on an upper portion of the second pixel.

In an embodiment, the light control pattern may be disposed on an upper portion of the first pixel and an upper portion of the second pixel.

In an embodiment, the second pixel further may include a third light emitting device electrically connected to the second circuit and controlled by a second light emitting control signal, and light emitted by the second light emitting device and light emitted by the third light emitting device may be of the same color.

In an embodiment, the first pixel may further include a fourth light emitting device electrically connected to the first circuit and controlled by the first light emitting control signal, and light emitted by the first light emitting device and light emitted by the fourth light emitting device may be of the same color.

In an embodiment, the gate lines may include first gate lines disposed parallel to each other across the first display area and corresponding to an entirety of the first display area and second gate lines disposed parallel to each other across the second display area and corresponding to an entirety of the second display area. The main data lines may include first main data lines disposed parallel to each other across the first display area and corresponding to an entirety of the first display area and second main data lines disposed parallel to each other across the second display area and corresponding to an entirety of the second display area. The sub data lines may include first sub data lines disposed parallel to each other across the first display area and corresponding to an entirety of the first display area. The sub data lines may include second sub data lines disposed parallel to each other across the second display area and corresponding to an entirety of the second display area.

In an embodiment, the first main data lines may respectively correspond to the first sub data lines and may be electrically connected to the first sub data lines, and the second main data lines may respectively correspond to the second sub data lines and may be electrically connected to the second sub data lines.

In an embodiment, the gate driver may include a first gate driver corresponding to the first gate lines and disposed in the second peripheral area, and a second gate driver corresponding to the second gate lines and disposed in the second peripheral area.

In an embodiment, a length of the first display area in the second direction may be equal to a length of the second display area in the second direction.

In an embodiment, the length of the first display area in the second direction may be different from the length of the second display area in the second direction.

A display device according to another embodiment of the present invention may include a substrate including a display area and peripheral area surrounding the display area. The peripheral area includes a first peripheral area extending in a first direction and a second peripheral area extending in a second direction intersecting the first direction, where a second length of the second peripheral area is longer than a first length of the first peripheral area. The display device includes data lines disposed in the display area on the substrate and extending in the first direction, main gate lines disposed in the display area on the substrate and extending in the second direction, sub gate lines disposed in the display area on the substrate and extending in the first direction, a data driver corresponding to the data lines and disposed in the second peripheral area on the substrate, a main gate driver corresponding to the main gate lines and disposed in the first peripheral area on the substrate, and a sub gate driver corresponding to the sub gate lines and disposed in the second peripheral area on the substrate.

In an embodiment, a quantity of the main gate lines is equal to a quantity of the sub gate lines.

In an embodiment, the main gate lines may respectively correspond to the sub gate lines and may be electrically connected to the sub gate lines.

In an embodiment, a line connecting a center point of the sub gate driver and a center point of the display area may be parallel to the first direction on a plane.

In an embodiment, a length of the sub gate driver in the second direction may be equal to a length of the main gate driver in the first direction.

In an embodiment, the sub gate driver may be disposed such that the sub gate driver is spaced apart from the data driver in the first direction on a plane, and the display area is interposed between the sub gate driver and the data driver.

Accordingly, aspects of the present disclosure provide a display device capable of a reduction or prevention of signal distortion supported by a large length ratio between the long side and the short side of the display device. For example, distortion of the gate signal in the center of the display device where the length ratio between the long side and the short side is large may be reduced or prevented. Accordingly, for example, the display quality of the display device may be improved. In some embodiments, the display device supports a modular design for each display area, and the modular design supports increasing the length of the long based on target criteria. Accordingly, the modular capability of the display device supports an increase in the ease of designing the display device.

### BRIEF DESCRIPTION OF THE DRAWINGS

The accompanying drawings, which are included to provide a further understanding of the inventive concept and are incorporated in and constitute a part of this specification, illustrate embodiments of the inventive concept together with the description.

FIG. 1 is a plan view illustrating a display device according to an embodiment of the present invention.

FIG. 2 is a plan view illustrating a display device according to another embodiment of the present invention.

FIG. 3 is a circuit diagram illustrating an example of a first pixel included in the display device of FIG. 2.

FIG. 4 is a circuit diagram illustrating an example of a second pixel included in the display device of FIG. 2.

FIG. 5 is a plan view illustrating an example of a first pixel of FIG. 3.

FIG. 6 is a plan view illustrating an example of a second pixel of FIG. 4.

FIG. 7 is a plan view illustrating another example of a second pixel of FIG. 4.

FIG. 8 is a plan view illustrating another example of a first pixel of FIG. 3.

FIG. 9 is a cross-sectional view taken along line I-I′ of FIG. 5.

FIG. 10 is a cross-sectional view taken along line II-II′ of FIG. 6.

FIG. 11 is a cross-sectional view taken along line III-III′ of FIG. 7.

FIG. 12 is a circuit diagram illustrating another example of a first pixel included in the display device of FIG. 2.

FIG. 13 is a circuit diagram illustrating another example of a second pixel included in the display device of FIG. 2.

FIG. 14 is a plan view illustrating a display device according to still another embodiment of the present invention.

### DETAILED DESCRIPTION

Illustrative, non-limiting embodiments will be more clearly understood from the following detailed description in conjunction with the accompanying drawings.

In this descriptions herein, a plane may be defined by a first direction D1 and a second direction D2 intersecting the first direction D1. For example, the second direction D2 may be perpendicular to the first direction D1. Additionally, a third direction D3 may be the normal direction of the plane. That is, for example, the third direction D3 may be perpendicular to the plane formed by the first direction D1 and the second direction D2.

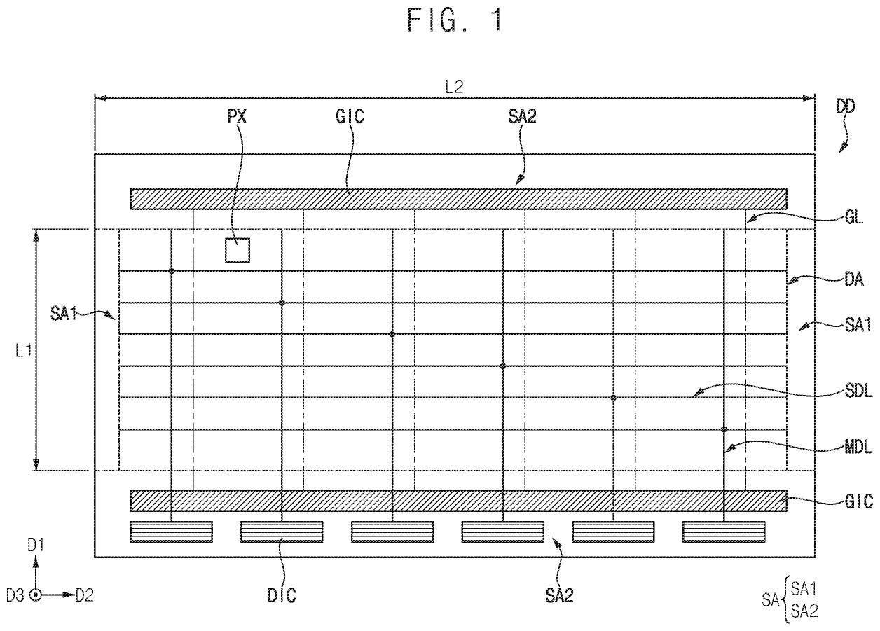

FIG. 1 is a plan view illustrating a display device according to an embodiment of the present invention.

Referring to FIG. 1, the display device DD may include a display area DA and a peripheral area SA. The display area DA may be surrounded by the peripheral area SA.

The display area DA may be an area that may display an image by generating light or adjusting the transmittance of light provided from an external light source. In an example, the peripheral area SA may be an area configured not to display an image. However, embodiments of the present disclosure are not necessarily limited thereto, and in some embodiments the peripheral area SA may display an image.

The peripheral area SA may include a first peripheral area SA1 and a second peripheral area SA2. The first peripheral area SA1 may be disposed on both sides of the display area DA in the second direction D2 on a plane. That is, for example, two first peripheral areas SA1 may be disposed such that the first peripheral areas SAL are spaced apart in the second direction D2, with the display area DA interposed between the first peripheral areas SA1. The first peripheral area SA1 may extend to a first length L1 in the first direction D1. In FIG. 1, the first peripheral area SA1 is illustrated as a rectangular shape, but embodiments supported by the present disclosure are not limited thereto.

The second peripheral area SA2 may be disposed on both sides of the display area DA in the first direction D1 on a plane. That is, for example, two second peripheral areas SA2 may be disposed such that the second peripheral areas SA2 are spaced apart in the first direction, with the display area DA interposed between the second peripheral areas SA2. The second peripheral area SA2 may extend to a second length L2 in the second direction D2. In FIG. 1, the second peripheral area SA2 is illustrated as a rectangular shape, but embodiments supported by the present disclosure are not limited thereto.

In an embodiment, the second length L2 may be longer than the first length L1. Specifically, for example, the second length L2 may be about three times or more than the first length L1. That is, for example, the display device DD may include a short side (e.g., of the first length L1) extending in the first direction D1 and a long side (e.g., of the second length L2) extending in the second direction D2.

The display device DD may include a gate driver GIC, a data driver DIC, gate lines GL, main data lines MDL, and sub data lines SDL.

The gate driver GIC may be disposed in the second peripheral area SA2. For example, the gate driver GIC may be disposed on both sides of the display area DA. Specifically, for example, two gate drivers GIC may be disposed spaced apart in the first direction D1, with the display area DA interposed between the gate drivers GIC. However, embodiments of the present disclosure are not necessarily limited thereto, and the gate driver GIC may be disposed on a single side of the display area DA. The gate driver GIC may correspond to the gate lines GL and may sequentially apply gate signals to the gate lines GL. In FIG. 1, a single gate driver GIC is illustrated as being disposed on each side of the display area DA, but embodiments supported by the present disclosure are not necessarily limited thereto. In another example, the display device DD may have a plurality of gate drivers GIC on each side of the display area DA.

The data driver DIC may be disposed in the second peripheral area SA2. For example, the data driver DIC may be disposed on one side of the display area DA. However, embodiments of the present disclosure are not necessarily limited thereto, and the data driver DIC may be disposed on both sides of the display area DA. The data driver DIC may correspond to the main data lines MDL and may apply a data signal to the main data lines MDL. Although FIG. 1 illustrates a plurality of data drivers DIC, embodiments of the present disclosure are not necessarily limited thereto, and in another example, the display device DD may include one data driver DIC.

The gate lines GL may be disposed in the display area DA. The gate lines GL may correspond to the gate driver GIC and may extend in the first direction D1. The gate lines GL may be disposed such that the gate lines GL are spaced apart in the second direction D2. The gate lines GL may transmit the gate signal to a pixel PX. In the example of FIG. 1, for convenience of explanation, the six gate lines GL are illustrated as disposed across the display area DA. However, embodiments of the present disclosure are not necessarily limited thereto, and the gate lines GL may vary depending on the embodiments. In the example of FIG. 1, the gate lines GL are all illustrated to have the same length, but embodiments supported by the present disclosure are not necessarily limited thereto, and the length of at least one of the gate lines GL may be different from the rest.

The main data lines MDL may be disposed in the display area DA. The main data lines MDL may correspond to the data driver DIC and may extend in the first direction D1. The main data lines MDL may be disposed such that the main data lines MDL are spaced apart in the second direction D2. The main gate lines MDL may transmit data signals to the pixel PX. In the example of FIG. 1, for convenience of explanation, the six main data lines MDL are illustrated as being disposed across the display area DA, but embodiments supported by the present disclosure are not necessarily limited thereto, and the quantity of the main data lines MDLs may vary based on the embodiments. In the example of FIG. 1, the main data lines MDL are all illustrated to have the same length, but embodiments supported by the present disclosure are not necessarily limited thereto, and the length of at least one of the main data lines MDL may be different from the rest.

The sub data lines SDL may be disposed in the display area DA. The sub data lines SDL may correspond to the main data lines MDL and may extend in the second direction D2. That is, for example, the main data lines MDL and the sub data lines SDL may be orthogonal to each other. The sub data lines SDL may be disposed such that the sub data lines SDL are spaced apart in the first direction D1. The sub data lines SDL may transmit the data signal applied from the main data lines MDL to the pixel PX. In the example of FIG. 1, for convenience of explanation, the six main data lines MDL are illustrated as being disposed across the display area DA, but embodiments supported by the present disclosure are not necessarily limited thereto, and the quantity of the main data lines MDL may vary based on the embodiments. In the example of FIG. 1, the main data lines MDL are all illustrated to have the same length, but embodiments supported by the present disclosure are not necessarily limited thereto, and the length of at least one of the main data lines MDL is different from the rest.

In an embodiment, the main data lines MDL and the sub data lines SDL may correspond one-to-one to each other and may be electrically connected. Expressed another way, the main data lines MDL may respectively correspond to the sub data lines SDL. For example, the main data lines MDL and the sub data lines SDL may be disposed in the same quantity in the display area DA, and the main data lines MDL and the sub data lines SDL may transmit the data signal to the pixel PX corresponding one-to-one to each other.

The display device DD according to embodiments of the present invention may include the gate driver GIC and the data driver DIC disposed in the second peripheral area SA2. In an example, the display device DD may include the gate lines GL, the main data lines MDL, and the sub data lines SDL disposed in the display area DA such that the gate signal and the data signal applied to the pixel PX may intersect. Accordingly, for example, signal distortion in a display device with a large length ratio between a long side and a short side may be reduced or prevented. For example, distortion of the gate signal in the center of a display device where the length ratio between the long side and the short side is large may be reduced or prevented. Accordingly, a display quality of the display device DD may be improved.

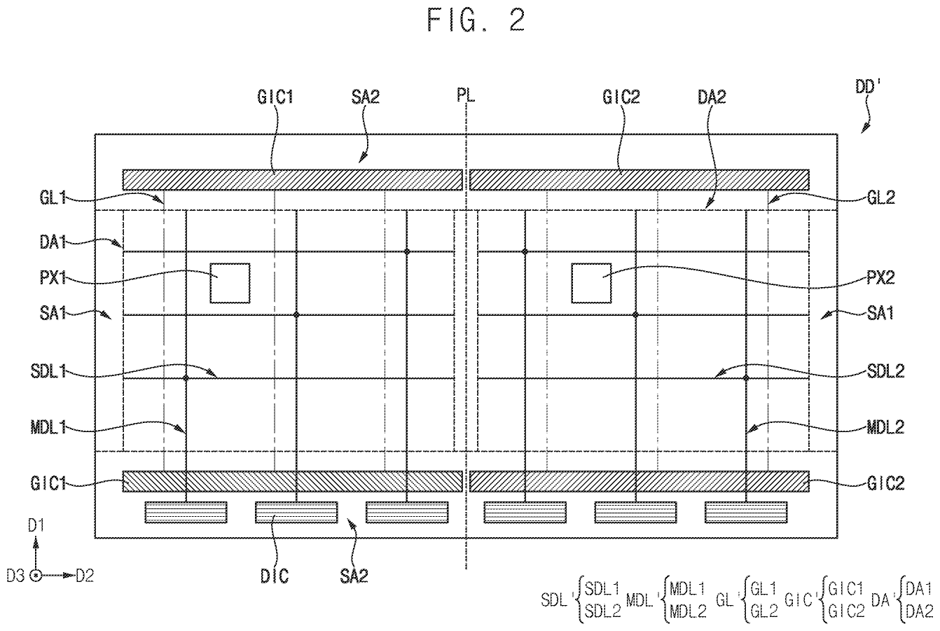

FIG. 2 is a plan view illustrating a display device according to another embodiment of the present invention. In contrast to the example of FIG. 1, FIG. 2 illustrates a display device divided by a dividing line PL. Accordingly, substantially the same configurations as those described in FIG. 1 may be included, and overlapping descriptions may be omitted or simplified.

Referring to FIG. 2, the display device DD′ may include a display area DA′ and the peripheral area SA. The display area DA′ may be surrounded by the peripheral area SA.

The peripheral area SA may include the first peripheral area SA1 and the second peripheral area SA2. Since the description of the peripheral area SA overlaps with the content described with reference to FIG. 1, repeated detailed description of the peripheral area SA is omitted for brevity.

The display area DA′ may include a first display area DA1 and a second display area DA2. In an embodiment, the first display area DA1 and the second display area DA2 may be adjacent to each other in the second direction D2. In the example of FIG. 2, the dividing line PL is illustrated as one, but aspects of the present disclosure support implementations in which the display device is divided by multiple dividing lines PL. That is, for example, the display area DA′ may be divided into three or more areas by multiple dividing lines PL.

In an embodiment, a length of the first display area DA1 in the second direction D2 may be equal to a length of the second display area DA2 in the second direction D2. In other words, the display area DA′ may be divided into the first display area DA1 and the second display area DA2 by the dividing line PL, in which the first display area DA1 is equal to the second display area DA2 (e.g., dimensions of the first display area DA1 are the same as dimensions of the second display area DA2).

In another embodiment, the length of the first display area DA1 in the second direction D2 may be different from the length of the second display area DA2 in the second direction D2. In other words, the display area DA′ may be divided into the first display area DA1 and the second display area DA2 by the dividing line PL, in which the first display area DA1 is not equal to the second display area DA2 (e.g., dimensions of the first display area DA1 are different from dimensions of the second display area DA2).

The display device DD′ may include a gate driver GIC′, a data driver DIC, gate lines GL′, main data lines MDL′, and sub data lines SDL′. Since the description of the data driver DIC overlaps with the content described with reference to FIG. 1, repeated detailed description will be omitted.

In an embodiment, the gate driver GIC′ may include a first gate driver GIC1 and a second gate driver GIC2. Specifically, for example, the first gate driver GIC1 may be disposed to correspond to the first display area DA1, and the second gate driver GIC2 may be disposed to correspond to the second display area DA2.

For example, the first gate driver GIC1 may be disposed on both sides of the first display area DA1. Specifically, for example, two first gate drivers GIC1 may be disposed such that the first gate drivers GIC1 are spaced apart in the first direction D1, with the first display area DA1 interposed between the first gate drivers GIC1. However, embodiments of the present disclosure are not necessarily limited thereto, and in some embodiments the first gate driver GIC1 may be disposed on a single side of the first display area DA1. The first gate driver GIC1 may correspond to the first gate lines GL1 and may sequentially apply a gate signal to the first gate lines GL1.

The second gate driver GIC2 may be disposed on both sides of the second display area DA2. Specifically, for example, two second gate drivers GIC2 may be disposed such that the second gate drivers GIC2 are spaced apart from each other in the first direction D1, with the second display area DA2 interposed between the second gate drivers GIC2. However, embodiments of the present disclosure are not necessarily limited thereto, and in some embodiments the second gate driver GIC2 may be disposed on a single side of the second display area DA2. The second gate driver GIC2 may correspond to the second gate lines GL2 and may sequentially apply a gate signal to the second gate lines GL2.

The gate lines GL′ may include the first gate lines GL1 and the second gate lines GL2.

The first gate lines GL1 may be disposed in the first display area DA1. For example, the first gate lines GL1 may be disposed parallel to each other across the first display area DA1 such that the first gate lines GL1 correspond to the entirety of the first display area DA1. Specifically, for example, the first gate lines GL1 may extend in the first direction D1 and may be spaced apart from each other in the second direction D2 and disposed in the first display area DA1. In the example of FIG. 2, for convenience of explanation, the three first gate lines GL1 are illustrated as being disposed across the first display area DA1. However, embodiments of the present disclosure are not necessarily limited thereto, and the quantity of first gate lines GL1 may vary based on embodiments. In the example of FIG. 2, the first gate lines GL1 are all illustrated to have the same length, but embodiments supported by the present disclosure are not necessarily limited thereto, and the length of at least one of the first gate lines GL1 may be different from the rest.

In an embodiment, the first gate lines GL1 may correspond to the first gate driver GIC1. That is, for example, the first gate driver GIC1 may apply a gate signal to the first gate lines GL1.

In an embodiment, the first gate driver GIC1 may apply gate signals to the first pixel PX1 via the first gate lines GL1.

The second gate lines GL2 may be disposed in the second display area DA2. For example, the second gate lines GL2 may be disposed parallel to each other across the second display area DA2 to correspond to an entirety of the second display area DA2. Specifically, for example, the second gate lines GL2 may extend in the first direction D1, and may be spaced apart from each other in the second direction D2 and disposed in the second display area DA2. In the example of FIG. 2, for convenience of explanation, the three second gate lines GL2 are illustrated as being disposed across the second display area DA2. However, embodiments of the present disclosure are not necessarily limited thereto, and the quantity of the second gate lines GL2 may vary based on embodiments. In the example of FIG. 2, the second gate lines GL2 are all illustrated to have the same length, but embodiments supported by the present disclosure are not necessarily limited thereto, and the length of at least one of the second gate lines GL2 may be different from the rest.

In an embodiment, the second gate lines GL2 may correspond to the second gate driver GIC2. That is, for example, the second gate driver GIC2 may apply a gate signal to the second gate lines GL2.

In an embodiment, the second gate driver GIC2 may apply gate signals to the second pixel PX2 via the second gate lines GL2.

The main data lines MDL′ may include first main data lines MDL1 and second main data lines MDL2.

The first main data lines MDL1 may be disposed in the first display area DA1. For example, the first main data lines MDL1 may be disposed parallel to each other across the first display area DA1 such that the first main data lines MDL1 correspond to an entirety of the first display area DA1. Specifically, for example, the first main data lines MDL1 may extend in the first direction D1 and are spaced apart from each other in the second direction D2 and are disposed in the first display area DA1. In the example of FIG. 2, for convenience of explanation, the three first main data lines MDL1 are illustrated as being disposed across the first display area DA1. However, embodiments of the present disclosure are not necessarily limited thereto, and the quantity of first main data lines MDL1 may vary based on embodiments. In the example of FIG. 2, the first main data lines MDL1 are all illustrated to have the same length, but embodiments supported by the present disclosure are not necessarily limited thereto, and the length of at least one of the first main data lines MDL1 may be different from the rest.

The second main data lines MDL2 may be disposed in the second display area DA2. For example, the second main data lines MDL2 may be disposed parallel to each other across the second display area DA2 to correspond to an entirety of the second display area DA2. Specifically, for example, the second main data lines MDL2 may extend in the first direction D1 and may be spaced apart from each other in the second direction D2 and disposed in the second display area DA2. In the example of FIG. 2, for convenience of explanation, the three second main data lines MDL2 are illustrated as being disposed across the second display area DA2. However, embodiments of the present disclosure are not necessarily limited thereto, and in some embodiments the quantity of second main data lines MDL2 may vary based on embodiments. In the example of FIG. 2, the second main data lines MDL2 are all illustrated to have the same length, but embodiments supported by the present disclosure are not necessarily limited thereto, and the length of at least one of the second main data lines MDL2 may be different from the rest.

The sub data lines SDL′ may include first sub data lines SDL1 and second sub data lines SDL2.

The first sub data lines SDL1 may be disposed in the first display area DA1. For example, the first sub data lines SDL1 may be disposed parallel to each other across the first display area DA1 and may be disposed to correspond to an entirety of the first display area DA1. Specifically, for example, the first sub data lines SDL1 may extend in the second direction D2 and are spaced apart from each other in the first direction D1 and are disposed in the first display area DA1. In the example of FIG. 2, for convenience of explanation, the three first sub-data lines SDL1 are illustrated as being disposed across the first display area DA1, but embodiments of the present disclosure are not necessarily limited thereto. The quantity of the first sub data lines SDL1 may vary based on embodiments. In the example of FIG. 2, the first sub data lines SDL1 are all illustrated to have the same length, but embodiments supported by the present disclosure are not necessarily limited thereto, and the length of at least one of the first sub data lines SDL1 may be different from the rest.

In an embodiment, the first sub data lines SDL1 may correspond one-to-one to the first main data lines MDL1 and may be electrically connected to transmit data signals. For example, the first sub data lines SDL1 may be respectively electrically connected to the first main data lines MDL1.

The second sub data lines SDL2 may be disposed in the second display area DA2. For example, the second sub data lines SDL2 may be disposed parallel to each other across the second display area DA2 to correspond to an entirety of the second display area DA2. Specifically, for example, the second sub data lines SDL2 may extend in the second direction D2 and may be spaced apart from each other in the first direction D1 and disposed in the second display area DA2. In the example of FIG. 2, for convenience of explanation, the three second sub data lines SDL2 are illustrated as being disposed across the second display area DA2, but embodiments of the present disclosure are not necessarily limited thereto. The quantity of the second sub data lines SDL2 may vary based on embodiments. In the example of FIG. 2, the second sub data lines SDL2 are all illustrated to have the same length, but embodiments supported by the present disclosure are not necessarily limited thereto, and the length of at least one of the second sub data lines SDL2 may be different from the rest.

In an embodiment, the second sub data lines SDL2 may correspond one-to-one to the second main data lines MDL2 and may be electrically connected to transmit a data signal.

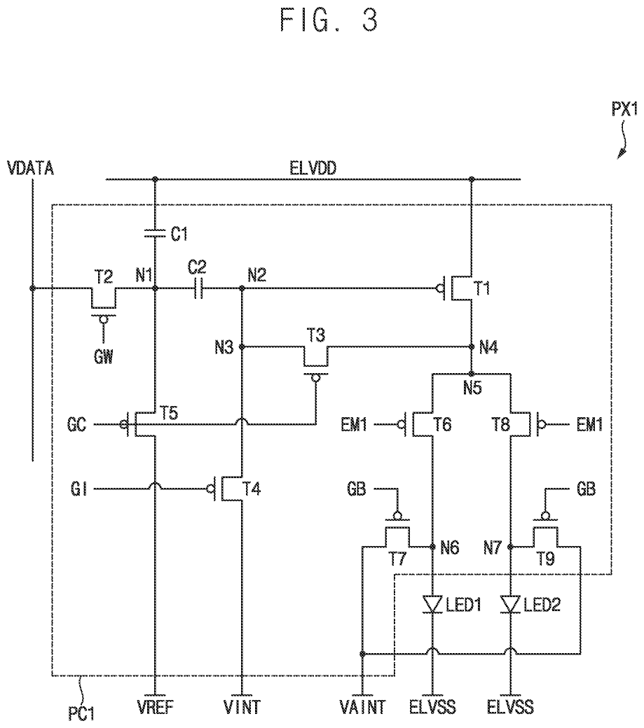

FIG. 3 is a circuit diagram illustrating an example of a first pixel included in the display device of FIG. 2.

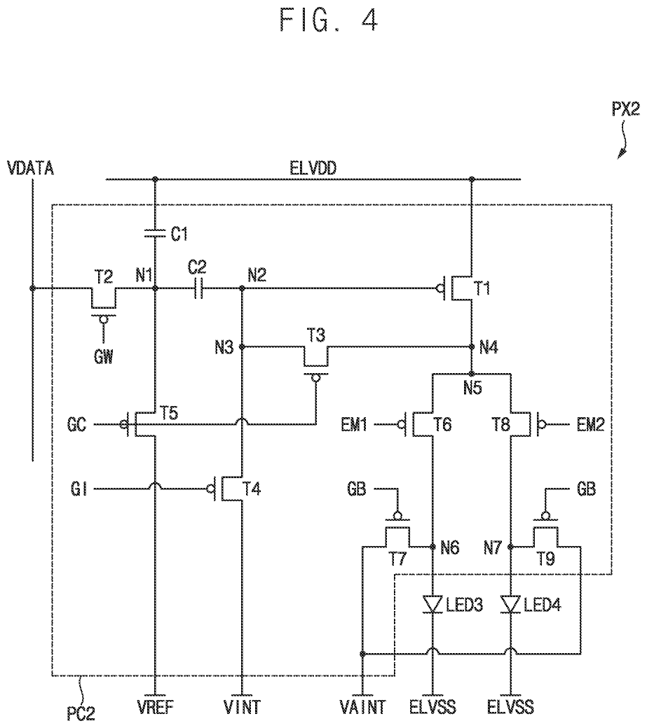

FIG. 4 is a circuit diagram illustrating an example of a second pixel included in the display device of FIG. 2.

Referring to FIG. 3 and FIG. 4, the first pixel PX1 may include a first circuit PC1, a first light emitting device LED1, and a second light emitting device LED2, and the second pixel PX2 may include a second circuit PC2, a third light emitting device LED3, and a fourth light emitting device LED4. The first circuit PC1 may provide a first driving current to the first light emitting device LED1 and the second light emitting device LED2, and the second circuit PC2 may provide a second driving current to the third light emitting device LED3 and the fourth light emitting device LED4. The first light emitting device LED1 and the second light emitting device LED2 may emit light of the same color based on the first driving current. For example, based on the driving current, light emitted by the first light emitting device LED1 and light emitted by the second light emitting device LED2 may be of the same color. In some aspects, the third light emitting device LED3 and the fourth light emitting device LED4 may emit light of the same color based on the second driving current. For example, based on the second driving current, light emitted by the third light emitting device LED3 and light emitted by the fourth light emitting device LED4 may be of the same color.

That is, for example, the first pixel PX1 may be electrically connected to the first circuit PC1, and the second pixel PX2 may be electrically connected to the second circuit PC2.

Each of the first and second circuits PC1, PC2 may include first to ninth transistors T1, T2, T3, T4, T5, T6, T7, T8, T9, a first capacitor C1, and a second capacitor C2.

The first transistor T1 may include a gate electrode, a first electrode, and a second electrode. The gate electrode of the first transistor T1 may be connected to a second node N2. A driving voltage ELVDD may be applied to the first electrode of the first transistor T1. The second electrode of the first transistor T1 may be connected to a fourth node N4.

The second transistor T2 may include a gate electrode, a first electrode, and a second electrode. A first gate signal GW may be applied to the gate electrode of the second transistor T2. A data voltage VDATA may be applied to the first electrode of the second transistor T2. The second electrode of the second transistor T2 may be connected to a first node N1.

The third transistor T3 may include a gate electrode, a first electrode, and a second electrode. A second gate signal GC may be applied to the gate electrode of the third transistor T3. The first electrode of the third transistor T3 may be connected to a third node N3. The second electrode of the third transistor T3 may be connected to the fourth node N4.

The fourth transistor T4 may include a gate electrode, a first electrode, and a second electrode. A third gate signal GI may be applied to the gate electrode of the fourth transistor T4. A first initialization voltage VINT may be applied to the first electrode of the fourth transistor T4. The second electrode of the fourth transistor T4 may be connected to a third node N3.

The fifth transistor T5 may include a gate electrode, a first electrode, and a second electrode. A second gate signal GC may be applied to the gate electrode of the fifth transistor T5. A reference voltage VREF may be applied to the first electrode of the fifth transistor T5. The second electrode of the fifth transistor T5 may be connected to the first node N1.

The sixth transistor T6 may include a gate electrode, a first electrode, and a second electrode. The first electrode of the sixth transistor T6 may be connected to the fifth node N5. The second electrode of the sixth transistor T6 may be connected to the sixth node N6. In an embodiment, the first emission control signal EM1 may be applied to the gate electrode of the sixth transistor T6 in the first and second circuits PC1 and PC2. That is, for example, the same light emission control signal (e.g., first emission control signal EM1) may be applied to the gate electrodes of the sixth transistors T6 in the first and second circuits PC1 and PC2.

The seventh transistor T7 may include a gate electrode, a first electrode, and a second electrode. The fourth gate signal GB may be applied to the gate electrode of the seventh transistor T7. A second initialization voltage VAINT may be applied to the first electrode of the seventh transistor T7. The second electrode of the seventh transistor T7 may be connected to the sixth node N6.

The eighth transistor T8 may include a gate electrode, a first electrode, and a second electrode. The first electrode of the eighth transistor T8 may be connected to a fifth node N5. The second electrode of the eighth transistor T8 may be connected to a seventh node N7. In an embodiment, in the first circuit PC1, the first emission control signal EM1 may be applied to the gate electrode of the eighth transistor T8, and in the second circuit PC2, a second emission control signal EM2 may be applied to the gate electrode of the transistor T8. That is, for example, a light emission control signal applied to the gate electrode of the eighth transistor T8 included in the first circuit PC1 and a light emission control signal applied to the gate electrode of the eighth transistor T8 included in the first circuit PC2 may be different.

The ninth transistor T9 may include a gate electrode, a first electrode, and a second electrode. A fourth gate signal GB may be applied to the gate electrode of the ninth transistor T9. A second initialization voltage VAINT may be applied to the first electrode of the ninth transistor T9. The second electrode of the ninth transistor T9 may be connected to a second node N7.

The first capacitor C1 may include a first electrode and a second electrode. A driving voltage ELVDD may be applied to the first electrode of the first capacitor C1. The second electrode of the first capacitor C1 may be connected to the first node N1. In an embodiment, the first capacitor C1 may be a storage capacitor.

The second capacitor C2 may include a first electrode and a second electrode. The first electrode of the second capacitor C2 may be connected to the first node N1. The second electrode of the second capacitor C2 may be connected to the second node N2. In an embodiment, the second capacitor C2 may be a hold capacitor.

Each of the first light emitting device LED1 and the third light emitting device LED3 may include a first electrode (e.g., an anode electrode) and a second electrode (e.g., a cathode electrode). The first electrode of each of the first light emitting device LED1 and the third light emitting device LED3 may be connected to the sixth node N6. A common voltage ELVSS may be applied to the second electrode of each of the first light emitting device LED1 and the third light emitting device LED3. In an embodiment, the first light emitting device LED1 and the third light emitting device LED3 may be controlled by the first light emitting control signal EM1.

Each of the second light emitting device LED2 and the fourth light emitting device LED4 may include a first electrode (e.g., an anode electrode) and a second electrode (e.g., a cathode electrode). The first electrode of each of the second light emitting device LED2 and the fourth light emitting device LED4 may be connected to the seventh node N7. A common voltage ELVSS may be applied to the second electrode of each of the second light emitting device LED2 and the fourth light emitting device LED4. In an embodiment, the second light emitting device LED2 may be controlled by the first emission control signal EM1, and the fourth light emitting device LED4 may be controlled by the second emission control signal EM2.

For example, when a voltage level of the first emission control signal EM1 is equal to an activation level, the eighth transistor T8 of the first circuit PC1, the ninth transistor T9 of the first circuit PC1, and the eighth transistor T8 of the second circuit PC2 may be turned on. Additionally, the first transistor T1 may also be turned on by the data voltage VDATA. In this case, in the first circuit PC1, the first driving current may pass through the first transistor T1 to drive the first light emitting device LED1 and the third light emitting device LED3. In some embodiments, in the second circuit PC2, the second driving current may pass through the first transistor T1 to drive the third light emitting device LED3.

For example, when a voltage level of the second emission control signal EM2 is equal to an activation level, the eighth transistor T8 of the second circuit PC2 may be turned on. In some embodiments, the first transistor T1 may also be turned on by the data voltage VDATA. In this case, in the second circuit PC2, the second driving current may pass through the first transistor T1 to drive the fourth light emitting device LED4.

For example, each of the first to ninth transistors T1, T2, T3, T4, T5, T6, T7, T8, and T9 may be a P-type thin film transistor. However, embodiments of the present invention are not limited thereto, and one or more of the first to ninth transistors T1, T2, T3, T4, T5, T6, T7, T8, and T9 may be an N-type thin film transistor.

However, in FIGS. 2 and 3, each of the first and second pixels PX1, PX2 is illustrated as including 9 transistors, 2 capacitors, and 2 light emitting devices, an embodiment of the present invention is not limited thereto. For example, each of the first and second pixels PX1, PX2 may include a quantity of transistors, capacitors, and/or light emitting devices different from the examples described herein.

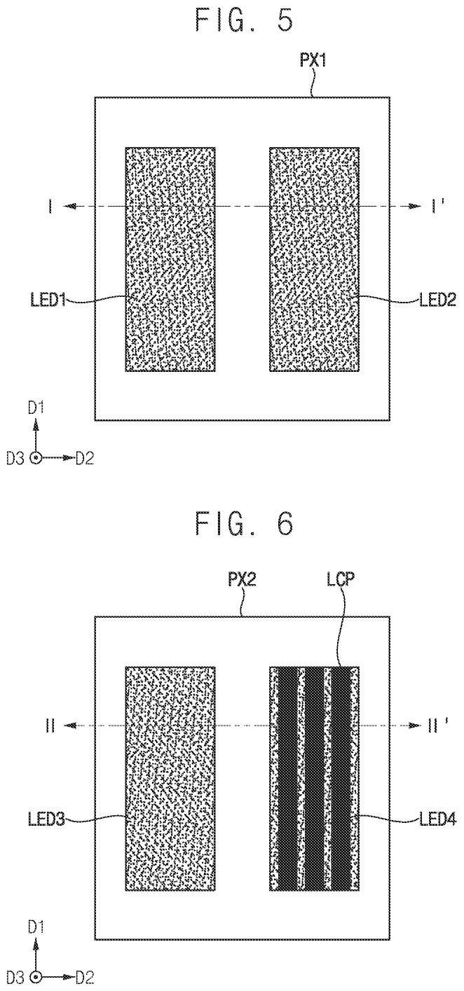

FIG. 5 is a plan view illustrating an example of a first pixel PX1 of FIG. 3. For example, FIG. 5 is a plan view schematically illustrating an example of the arrangement of the light emitting devices LED1 and LED2 of the first pixel PX1 of FIG. 3.

Referring to FIG. 5, the first pixel PX1 may include the first light emitting device LED1 and the second light emitting device LED2.

In an embodiment, the first light emitting device LED1 and the second light emitting device LED2 may emit light of the same color. For example, the first light emitting device LED1 and the second light emitting device LED2 may each emit red light. In another example, the first light emitting device LED1 and the second light emitting device LED2 may each emit green light. In still another example, the first light emitting device LED1 and the second light emitting device LED2 may each emit blue light. However, embodiments of the present invention are not limited thereto, and the first light emitting device LED1 and the second light emitting device LED2 may each emit light of the same color, in which the color is other than red, green, and blue.

FIG. 6 is a plan view illustrating an example of a second pixel PX2 of FIG. 4.

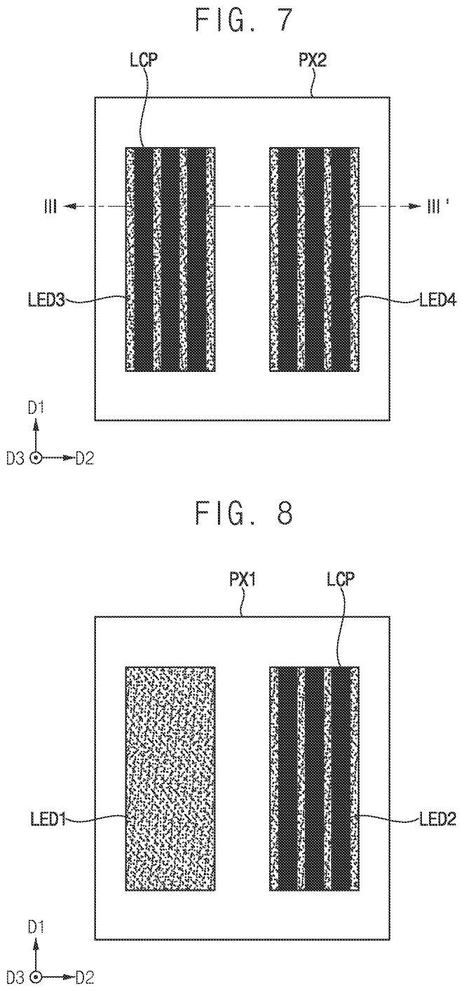

FIG. 7 is a plan view illustrating another example of a second pixel PX2 of FIG. 4.

For example, FIGS. 6 and 7 are plan views schematically illustrating examples of arrangement of the light emitting devices LED3 and LED4 of the second pixel PX2 of FIG. 4.

In an embodiment, the third light emitting device LED3 and the fourth light emitting device LED4 may emit light of the same color. For example, the third light emitting device LED3 and the fourth light emitting device LED4 may each emit red light. In another example, the third light emitting device LED3 and the fourth light emitting device LED4 may each emit green light. In still another example, the third light emitting device LED3 and the fourth light emitting device LED4 may each emit blue light. However, embodiments of the present invention are not limited thereto, and the third light emitting device LED3 and the fourth light emitting device LED4 may each emit light of the same color, in which the color is other than red, green, and blue.

As described in FIGS. 5 to 7, the first to fourth light emitting devices LED1, LED2, LED3, and LED4 may all emit light of the same color. For example, the first to fourth light emitting devices LED1, LED2, LED3, and LED4 may each emit red light. In another example, the first to fourth light emitting devices LED1, LED2, LED3, and LED4 may each emit green light. In still another example, the first to fourth light emitting devices LED1, LED2, LED3, and LED4 may each emit blue light. However, embodiments of the present invention are not limited thereto, and the first to fourth light emitting devices LED1, LED2, LED3, and LED4 may emit light of the same color, in which the color is other than red, green, and blue.

A light control pattern LCP may be disposed on the second pixel PX2. Specifically, for example, the light control pattern LCP may overlap the third light emitting device LED3 and/or the fourth light emitting device LED4 of the second pixel PX2 on a plane.

That is, for example, in an embodiment, the light control pattern LCP may overlap one of the third light emitting device LED3 and the fourth light emitting device LED4 on a plane, and the light control pattern LCP may be spaced apart from the other on a plane. For example, as illustrated in FIG. 6, the light control pattern LCP overlaps the fourth light emitting device LED4 on a plane and is spaced apart from the third light emitting device LED3 on the plane.

In another embodiment, as illustrated in FIG. 7, the light control pattern LCP may overlap both the third light emitting device LED3 and the fourth light emitting device LED4 on a plane.

The light control pattern LCP may control the viewing angle by blocking part of the light emitted from the third light emitting device LED3 and/or the fourth light emitting device LED4. In an embodiment, the light control pattern LCP may include an inorganic material. In an embodiment, the light control pattern LCP may include molybdenum-tantalum oxide. For example, the light control pattern LCP may include one or more of MTO, MTO/Mo, MTO/Cu, MTO/Al, MTO/Mo/MTO, MTO/Cu/MTO, MTO, Al/MTO, and the like. The light control panel LCP may include MTO, MTO/Mo, MTO/Cu, MTO/Al, MTO/Mo/MTO, MTO/Cu/MTO, MTO, Al/MTO, or the like, alone or in combination with each other. However, the light control pattern LCP is not limited to including MTO, and the light control pattern LCP may include various materials with relatively low transmittance and reflectance and relatively high absorption.

In another embodiment, the light control pattern LCP may include an organic material containing a light blocking material such as, for example, black pigment, black dye, and the like.

For example, the display device DD′ may support a mode that controls the viewing angle in the second direction DR2 (or the first direction DR1). In an example, when an image is to be displayed in the mode that controls the viewing angle in the second direction DR2 (or the first direction DR1), a voltage level of the first light emission control signal is equal to an inactivation level, and a voltage level of the second emission control signal is equal to an activation level. In this case, the first and second light emitting devices LED1, LED2 disposed in the first display area DA1 may be turned off, and the third light emitting device LED3 disposed in the second display area DA2 may be turned off, and the fourth light emitting device LED4 disposed in the second display area DA2 may be turned on. Accordingly, for example, the light control pattern LCP may block a portion of the light emitted from the fourth light emitting device LED4 traveling in the second direction DR2. Accordingly, for example, the image may not be visible in the second direction DR2 of the display device DD′.

For example, the display device DD′ may support a mode that does control the viewing angle in the second direction DR2 (or the first direction DR1). In an example, when an image is to be displayed in the mode that does not control the viewing angle, the voltage level of each of the first and second emission control signals may be equal to an activation level. In this case, the first and second light emitting devices LED1, LED2 disposed in the first display area DA1 and the third and fourth light emitting devices LED1, LED2 disposed in the second display area DA2 may all be turned on. Accordingly, for example, the image may be viewed in both the first direction DR1 and the second direction DR2 of the display device DD′.

In an embodiment, the display device according to embodiments of the present invention may be applied to a vehicle display. The display device may display an image at a narrow viewing angle or at a wide viewing angle. Therefore, the driver's (or passenger's) viewing angle may be controlled in accordance with driver (or passenger) preference.

FIG. 8 is a plan view illustrating another example of a first pixel PX1 of FIG. 3.

Referring to FIG. 8, the light control pattern LCP may also be disposed on an upper portion of the first pixel PX1. Specifically, for example, the light control pattern LCP may overlap the first light emitting device LED1 and/or the second light emitting device LED2 of the first pixel PX2 on a plane.

That is, for example, in an embodiment, the light control pattern LCP may overlap one of the first light emitting device LED1 and the second light emitting device LED2 on a plane, and the light control pattern LCP may be spaced apart from the other on the plane. For example, as illustrated in FIG. 8, the light control pattern LCP may overlap the second light emitting device LED2 on a plane and may be spaced apart from the first light emitting device LED1 on the plane.

In another embodiment, not illustrated in FIG. 8, the light control pattern LCP may overlap both the first light emitting device LED1 and the second light emitting device LED2 on a plane.

That is, for example, as illustrated in FIGS. 5 to 8, the light control pattern LCP may overlap the first pixel PX1 and/or the second pixel PX2 on a plane.

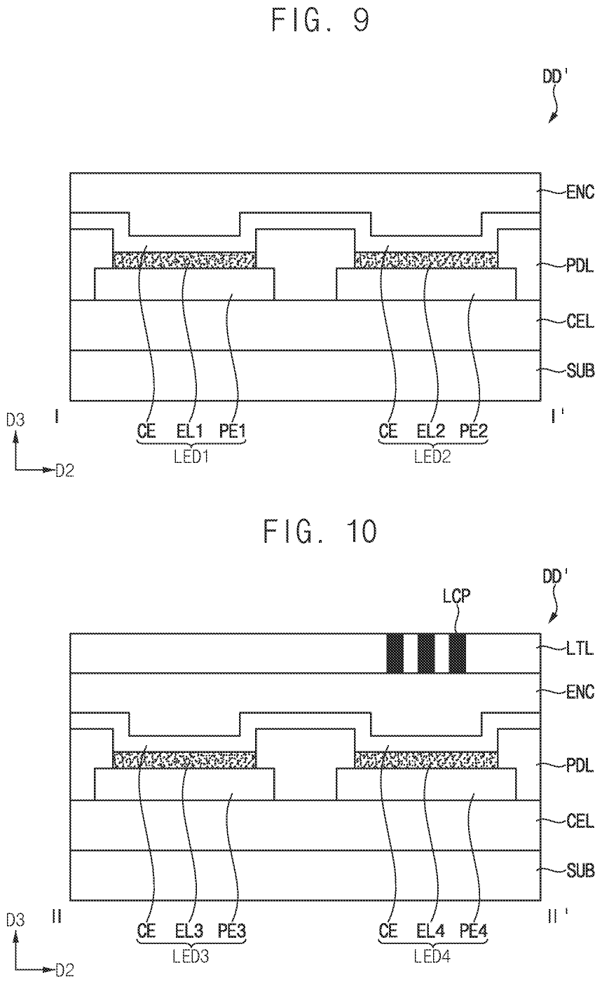

FIG. 9 is a cross-sectional view taken along line I-I′ of FIG. 5.

Referring to FIG. 9, the display device DD′ according to an embodiment of the present invention may include a substrate SUB, a circuit element layer CEL, a pixel defining layer PDL, the first light emitting device LED1, the second light emitting device LED2, and an encapsulation layer ENC.

The substrate SUB may be an insulating substrate including a transparent material or an opaque material. For example, the substrate SUB may include glass. In some embodiments, the substrate SUB may include plastic. In this case, for example, the display device DD may be a flexible display device.

The circuit element layer CEL may be disposed on the substrate SUB. The circuit element layer CEL may include at least one transistor and at least one insulating layer. For example, the circuit element layer CEL may include the first circuit PC1 of FIG. 3.

The first light emitting device LED1 and the second light emitting device LED2 may be disposed on the circuit element layer CEL.

The first light emitting device LED1 may include a first pixel electrode PE1, a first light emitting layer EL1, and a common electrode CE. Specifically, for example, the first light emitting layer EL1 may be located on the first pixel electrode PE1, and the common electrode CE may be located on the first light emitting layer EL1.

The second light emitting device LED2 may include a second pixel electrode PE2, a second light emitting layer EL2, and the common electrode CE. Specifically, for example, the second light emitting layer EL2 may be located on the second pixel electrode PE2, and the common electrode CE may be located on the second light emitting layer EL2.

Each of the first and the second pixel electrodes PE1 and PE2 may include metal, alloy, metal nitride, conductive metal oxide, transparent conductive material, or the like, alone or in combination with each other. In some embodiments, the first and the second pixel electrodes PE1 and PE2 are formed through the same process and may include the same material.

A pixel defining layer PDL may be disposed on the first and the second pixel electrodes PE1 and PE2. The pixel defining layer PDL may expose at least a portion of each of the first and the second pixel electrodes PE1 and PE2. The pixel defining layer PDL may include an inorganic insulating material or an organic insulating material.

The first light emitting layer EL1 and the second light emitting layer EL2 may be disposed on the first pixel electrode PE1 and the second pixel electrode PE2, respectively. The first emission layer EL1 and the second emission layer EL2 may emit light of the same color. For example, the first light emitting layer EL1 and the second light emitting layer EL2 may each emit red light. In another example, the first emission layer EL1 and the second emission layer EL2 may each emit green light. In another example, the first light emitting layer EL1 and the second light emitting layer EL2 may each emit blue light. However, embodiments of the present invention are not limited thereto, and the first and second light emitting layers EL1 and EL2 may emit light of the same color, in which the color is other than red, green, and blue.

The common electrode CE may be disposed on the first emission layer EL1 and the second emission layer EL2. The common electrode CE may be disposed on an entirety of the surface of the display area DA. For example, the common electrode CE may include metal, alloy, metal nitride, conductive metal oxide, transparent conductive material, or the like. The common electrode CE may include one or a combination of any of metal, alloy, metal nitride, conductive metal oxide, transparent conductive material, or the like.

An encapsulation layer ENC may be disposed on the common electrode CE. The encapsulation layer ENC may protect the first light emitting device LED1 and the second light emitting device LED2 from external moisture, heat, shock, and the like. Although not illustrated, the encapsulation layer ENC may include at least one inorganic encapsulation layer and at least one organic encapsulation layer.

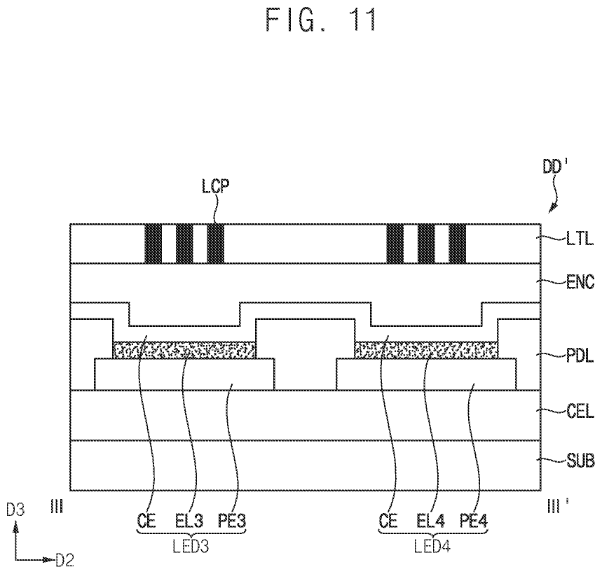

FIG. 10 is a cross-sectional view taken along line II-II′ of FIG. 6.

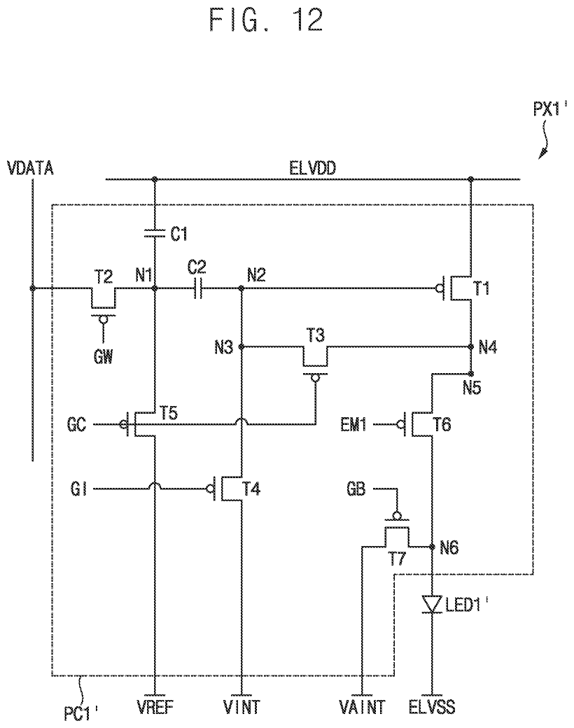

FIG. 11 is a cross-sectional view taken along line III-III′ of FIG. 7.

Configurations described with reference to FIG. 10 and FIG. 11 may be substantially the same as those described with reference to FIG. 9 except for the light control pattern LCP and the light transmissive layer LTL. Therefore, overlapping explanations may be omitted or simplified.

Referring to FIG. 10 and FIG. 11, the display device DD′ may include the substrate SUB, the circuit element layer CEL, the third light emitting device LED3, the fourth light emitting device LED4, a pixel defining layer PDL, the encapsulation layer ENC, a light transmissive layer LTL, and the light control pattern LCP.

The circuit element layer CEL may include at least one transistor and at least one insulating layer. For example, the circuit element layer CEL may further include the second circuit PC2 of FIG. 4.

The third light emitting device LED3 and the fourth light emitting device LED4 may be disposed on the circuit element layer CEL.

The third light emitting device LED3 may include a third pixel electrode PE3, a third light emitting layer EL3, and a common electrode CE. Specifically, for example, the third light emitting layer EL3 may be located on the third pixel electrode PE3, and the common electrode CE may be located on the third light emitting layer EL3.

The fourth light emitting device LED4 may include a fourth pixel electrode PE4, a fourth light emitting layer EL4, and the common electrode CE. Specifically, for example, the fourth light emitting layer EL4 may be located on the fourth pixel electrode PE4, and the common electrode CE may be located on the fourth light emitting layer ELA.

A pixel defining layer PDL may be disposed on the third and the fourth pixel electrodes PE3 and PE4. The pixel defining layer PDL may expose at least a portion of each of the third and the fourth pixel electrodes PE3 and PE4.

The third light emitting layer EL3 and the fourth light emitting layer EL4 may be disposed on the third pixel electrode PE3 and the fourth pixel electrode PE4, respectively. The third emission layer EL3 and the fourth emission layer EL4 may emit light of the same color. For example, the third light emitting layer EL3 and the fourth light emitting layer EL4 may each emit red light. Optionally, the third light emitting layer EL3 and the fourth light emitting layer EL4 may each emit green light of the same color or blue light of the same color. However, embodiments of the present disclosure are not limited thereto, and the third light emitting layer EL3 and the fourth light emitting layer EL4 may each emit light of a mixed color of red light, green light, and blue light.

The common electrode CE may be disposed on the third light emitting layer EL3 and the fourth light emitting layer EL4. In some embodiments, the encapsulation layer ENC may be disposed on the common electrode CE.

The light transmissive layer LTL may be disposed on the encapsulation layer ENC. The light transmissive layer LTL may fill the space between the light control patterns LCP. In an example, the light transmissive layer LTL may include an organic insulating material with relatively high light transmittance. The light transmissive layer LTL may have a substantially flat top surface.

The light control pattern LCP may be disposed such that the light control pattern LCP overlaps the third light emitting device LED3 and/or the fourth light emitting device LED4 on a plane. For example, as illustrated in FIG. 10, the light control pattern LCP may not be disposed on the third light emitting device LED3, but may be disposed on the fourth light emitting device LED4. In another example, as illustrated in FIG. 11, the light control pattern LCP may be disposed on both the third light emitting device LED3 and the fourth light emitting device LED4.

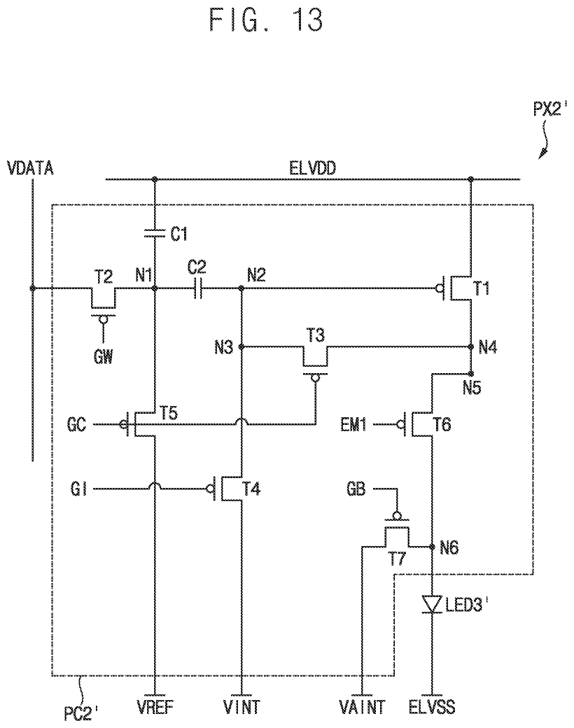

FIG. 12 is a circuit diagram illustrating another example of a first pixel PX1′ included in the display device of FIG. 2.

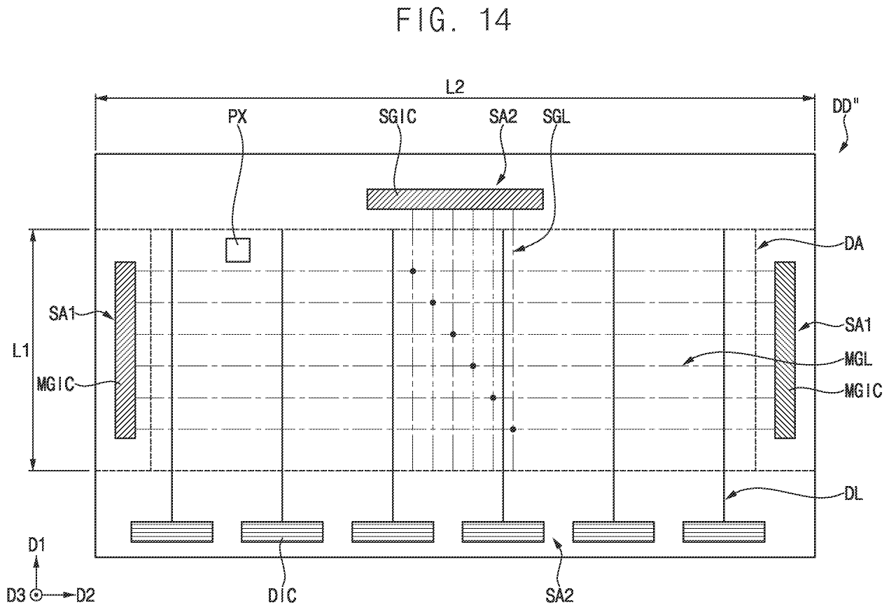

FIG. 13 is a circuit diagram illustrating another example of a second pixel PX2′ included in the display device of FIG. 2.

A first pixel PX1′ described with reference to FIG. 12 may be substantially the same as the first pixel PX1 described with reference to FIG. 3. except that an eighth transistor T8, a ninth transistor T9, and the second light emitting device LED2 are omitted. Therefore, overlapping explanations may be omitted or simplified.

A second pixel PX2′ described with reference to FIG. 13 may be substantially the same as the first pixel PX2 described with reference to FIG. 4. except that the eighth transistor T8, the ninth transistor T9, and the second light emitting device LED4 are omitted. Therefore, overlapping explanations may be omitted or simplified.

Referring to FIG. 12, the first pixel PX1′ may include a first circuit PC1′ and a first light emitting device LED1′. The first circuit PC1′ may include first to seventh transistors T1, T2, T3, T4, T5, T6, T7, a first capacitor C1, and a second capacitor C2. In an embodiment, the first pixel PX1′ may include a single light emitting device.

Referring to FIG. 13, the second pixel PX2′ may include a second circuit PC2′ and a third light emitting device LED3′. The second circuit PC2′ may include first to seventh transistors T1, T2, T3, T4, T5, T6, T7, a first capacitor C1, and a second capacitor C2. In an embodiment, the second pixel PX2′ may include a single light emitting device.

The display device DD′ according to embodiments of the present invention may include the display area DA′ divided into two or more areas. For example, the display device DD′ may be divided into the first display area DA1 and the second display area DA2 to control the viewing angle. Accordingly, the display device DD′ may display an image with a narrow viewing angle or with a wide viewing angle.

In accordance with one or more embodiments of the present disclosure, the light emitting devices disposed in one area of the display area DA′ may be independently controlled by different light emission control signals. Accordingly, for example, even when an image is displayed at a narrow viewing angle where the viewing angle in a specific direction is controlled, the luminous efficiency of the display device DD′ may be maintained (e.g., such that the luminous efficiency is not reduced).

In an example, when the display device DD′ is divided into the first display area DA1 and the second display area DA2, the display device DD′ may include the first gate driver GIC1 disposed in the second peripheral area SA2, corresponding to the first display area DA1, the second gate driver GIC2 disposed in the second peripheral area SA2, corresponding to the second display area DA2, and the data driver DIC disposed in the second peripheral area SA2. In an example, the display device DD′ may include the gate lines GL′, the main data lines MDL′, and the sub data lines SDL′ disposed in the display area DA′ so that the gate signal and the data signal applied to each of the first pixel (e.g., PX1, PX1′) and the second pixel (e.g., PX2, PX2′) may intersect. Accordingly, signal distortion in a display device with a large length ratio between the long side and the short side may be reduced or prevented. For example, distortion of the gate signal in the center of the display device DD′ where the length ratio between the long side and the short side is large may be reduced or prevented. Accordingly, the display quality of the display device DD′ may be improved.

FIG. 14 is a plan view illustrating a display device according to still another embodiment of the present invention. Hereinafter, among the components described with reference to FIG. 14, repeated description of parts that overlap with the components described with reference to FIG. 1 may be omitted or simplified.

Referring to FIG. 14, the display device DD″ may include the display area DA and the peripheral area SA. The display area DA may be surrounded by the peripheral area SA.

The peripheral area SA may include the first peripheral area SA1 and the second peripheral area SA2.

The display device DD″ may include a main gate driver MGIC, a sub gate driver SGIC, a data driver DIC, main gate lines MGL, sub gate lines SGL, and data lines DL.

The main gate driver MGIC may be disposed on both sides of the display area DA. Specifically, for example, two main gate drivers MGIC may be disposed such that the main gate drivers MGIC are spaced apart from each other in the second direction D2, with the display area DA interposed between the main gate drivers MGIC. However, embodiments of the present disclosure are not necessarily limited thereto, and in some embodiments the main gate driver MGIC may be disposed on a single side of the display area DA. The main gate driver MGIC may correspond to the main gate lines MGL and may sequentially apply gate signals to the main gate lines MGL.

The sub gate driver SGIC may be disposed in the second peripheral area SA2. Specifically, for example, the sub gate driver SGIC may be disposed on one side of the display area DA. However, embodiments of the present disclosure are not necessarily limited thereto, and in some embodiments the sub gate driver SGIC may be disposed on both sides of the display area DA. For example, two sub gate drivers SGIC may be disposed such that the sub gate drivers SGIC are spaced apart from each other in the first direction D1, with the display area DA interposed between the sub gate drivers SGIC. The sub gate driver SGIC may correspond to the sub gate lines SGL and may sequentially apply gate signals to the sub gate lines SGL.

The data driver DIC may be disposed in the second peripheral area SA2. Specifically, for example, the data driver DIC may be disposed on one side of the display area DA. However, embodiments of the present disclosure are not necessarily limited thereto, and one or more data drivers DIC may be disposed on each side of the display area DA, such that the data drivers DIC are spaced apart in the first direction D1, with the display area DA interposed between the data drivers DIC. The data driver DIC may correspond to the data lines DL and apply a data signal to the data lines DL.

In an embodiment, an imaginary line connecting the center point of the sub gate driver SGIC and the center point of the display area DA may be parallel to the first direction D1. That is, for example, the sub gate lines SGL corresponding to the sub gate driver SGIC may be disposed in the center of the display area DA.

In an embodiment, the length of the sub gate driver SGIC in the second direction D2 may be equal to the length of the main gate driver MGIC in the first direction D1. Accordingly, the quantity of the sub gate lines SGL corresponding to the sub gate driver SGIC and the quantity of the main gate lines MGL corresponding to the main gate driver MGIC may be the same. However, embodiments of the present disclosure are not necessarily limited thereto, and the quantity of main gate lines MGL and the quantity of sub gate lines SGL may vary based on embodiments.

The main gate lines MGL may be disposed in the display area DA. The main gate lines MGL may correspond to the main gate driver MGIC and may extend in the second direction D2. The main gate lines MGL may be disposed such that the main gate lines MGL are spaced apart in the first direction D1. The main gate lines MGL may transmit the main gate signal to the pixel PX. In the example of FIG. 14, for convenience of explanation, six main gate lines MGL are illustrated as being disposed across the display area DA, but embodiments supported by the present disclosure are not necessarily limited thereto, and the quantity of the main gate lines MGLs may vary based on the embodiments. In the example of FIG. 14, the main gate lines MGL are all illustrated to have the same length, but embodiments supported by the present disclosure are not necessarily limited thereto, and the length of at least one of the main gate lines MGL may be different from the rest.

In an embodiment, the main gate lines MGL may include a metal with low resistivity. For example, the main gate lines MGL may include aluminum-based metals such as, for example, aluminum (Al) and aluminum alloys, silver-based metals such as, for example, silver (Ag) and silver alloys, and copper-based metals such as, for example, copper (Cu) and copper alloys, molybdenum-based metals such as, for example, molybdenum (Mo) and molybdenum alloys, chromium (Cr), titanium (Ti), and tantalum (Ta), and the like. The main gate lines MGL may include any of elements described herein, alone or in combination with each other.

The sub gate lines SGL may be disposed in the display area DA. The sub gate lines SGL may correspond to the sub gate driver SGIC and may extend in the first direction D1. That is, for example, the sub gate lines SGL may be perpendicular to the main gate lines MGL. The sub gate lines SGL may be disposed such that the sub gate lines SGL are spaced apart in the second direction D2. The sub gate lines SGL may transmit the sub gate signal to the main gate lines MGL. In the example of FIG. 14, for convenience of explanation, six sub gate lines SGL are illustrated as being disposed across the display area DA. However, embodiments of the present disclosure are not necessarily limited thereto, and the sub gate lines the quantity of SGLs may vary based on the embodiments. In the example of FIG. 14, the main gate lines SGL are all illustrated to have the same length, but embodiments supported by the present disclosure are not necessarily limited thereto, and the length of at least one of the sub gate lines SGL may be different from the rest.

In an embodiment, the main gate lines MGL and the sub gate lines SGL may correspond to each other one-to-one and may be electrically connected.

The sub gate driver SGIC may transmit an additional gate signal to the main gate lines MGL through the sub gate lines SGL, which may thereby reduce or prevent signal distortion in the center of the display area DA. For example, transmitting the additional gate signal may reduce or prevent the signal distortion. Accordingly, for example, aspects of the present disclosure described herein support a display device with a large length ratio between the long side and the short side, for which signal distortion may be reduced or prevented.

The data lines DL may be disposed in the display area DA. The data lines DL may correspond to the data driver DIC and may extend in the first direction D1. The data lines DL may be disposed such that the data lines DL are spaced apart in the second direction D2. The data lines DL may apply data signals to the pixel PX. In the example of FIG. 14, for convenience of explanation, six data lines DL are illustrated as being disposed across the display area DA. However, embodiments of the present disclosure are not necessarily limited thereto, and the quantity of the data lines DL may vary based on the embodiments. In the example of FIG. 14, the data lines DL are all illustrated to have the same length, but embodiments supported by the present disclosure are not necessarily limited thereto, and the length of at least one of the data lines DL may be different from the rest.

A display device according to various embodiments of the present invention may include a display area DA and a peripheral area SA surrounding the display area DA, and the peripheral area SA may include the first peripheral area SA1 having a length L1 and the second peripheral area SA2 having a second length L2 longer than the first length L1.

In some aspects, the display device may include a gate driver and a data driver disposed in the second peripheral area SA2. In some aspects, the display device may have an arrangement structure of signal lines (e.g., gate lines and data lines) where the flows of gate signals and data signals applied to the pixel may intersect each other. Accordingly, signal distortion in a display device with a large length ratio between the long side and the short side may be reduced or prevented. For example, distortion of the gate signal in the center of the display device where the length ratio between the long side and the short side is large may be reduced or prevented. Accordingly, the display quality of the display device may be improved.

In some embodiments, modular design may be possible for each display area, and the example aspects of the display device support increasing the length of the long side according to a target length. Accordingly, the ease of designing the display device may be improved.

Although certain embodiments and implementations have been described herein, other embodiments and modifications will be apparent from this description. Accordingly, the inventive concepts are not limited to such embodiments, but rather to the broader scope of the appended claims and various obvious modifications and equivalent arrangements as would be apparent to a person of ordinary skill in the art.

What is claimed is:

1. A display device comprising:
a substrate including:
a display area; and
a peripheral area surrounding the display area and including a first peripheral area extending in a first direction and a second peripheral area extending in a second direction intersecting the first direction, wherein a second length of the second peripheral area is longer than a first length of the first peripheral area;
gate lines disposed in the display area on the substrate and extending in the first direction;
main data lines disposed in the display area on the substrate and extending in the first direction;
sub data lines disposed in the display area on the substrate and extending in the second direction;
a gate driver corresponding to the gate lines and disposed in the second peripheral area on the substrate; and
a data driver corresponding to the main data lines and disposed in the second peripheral area on the substrate.

2. The display device of claim 1, wherein the main data lines respectively correspond to the sub data lines and are electrically connected to the sub data lines.

3. The display device of claim 1, wherein the second length is about three times or more than the first length.

4. The display device of claim 1, wherein the display area includes a first display area and a second display area adjacent to each other.

5. The display device of claim 4, further comprising:
a first pixel disposed in the first display area on the substrate and including:
a first circuit; and
a first light emitting device electrically connected to the first circuit and controlled by a first light emission control signal;
a second pixel disposed in the second display area on the substrate and including:
a second circuit; and
a second light emitting device electrically connected to the second circuit and controlled by the first light emission control signal; and
a light control pattern disposed on at least one of the first pixel and the second pixel, wherein the light control pattern blocks at least one of a portion of light emitted from the first pixel and a portion of light emitted from the second pixel.

6. The display device of claim 5, wherein the light control pattern is not disposed on an upper portion of the first pixel and is disposed on an upper portion of the second pixel.

7. The display device of claim 5, the light control pattern is disposed on an upper portion of the first pixel and an upper portion of the second pixel.

8. The display device of claim 5, wherein the second pixel further includes a third light emitting device electrically connected to the second circuit and controlled by a second light emitting control signal, and
light emitted by the second light emitting device and light emitted by the third light emitting device are of a same color.

9. The display device of claim 5, wherein the first pixel further includes a fourth light emitting device electrically connected to the first circuit and controlled by the first light emission control signal, and
light emitted by the first light emitting device and light emitted by the fourth light emitting device are of a same color.

10. The display device of claim 4, wherein:
the gate lines include:
first gate lines disposed parallel to each other across the first display area and corresponding to an entirety of the first display area; and
second gate lines disposed parallel to each other across the second display area and corresponding to an entirety of the second display area,
the main data lines include:
first main data lines disposed parallel to each other across the first display area and corresponding to the entirety of the first display area; and
second main data lines disposed parallel to each other across the second display area and corresponding to the entirety of the second display area, and
the sub data lines include:
first sub data lines disposed parallel to each other across the first display area and corresponding to the entirety of the first display area; and
second sub data lines disposed parallel to each other across the second display area and corresponding to the entirety of the second display area.

11. The display device of claim 10, wherein the first main data lines respectively correspond to the first sub data lines and are electrically connected to the first sub data lines, and
the second main data lines respectively correspond to the second sub data lines and are electrically connected to the second sub data lines.

12. The display device of claim 10, wherein the gate driver includes:
a first gate driver corresponding to the first gate lines and disposed in the second peripheral area; and
a second gate driver corresponding to the second gate lines and disposed in the second peripheral area.

13. The display device of claim 4, wherein a length of the first display area in the second direction is equal to a length of the second display area in the second direction.

14. The display device of claim 4, wherein a length of the first display area in the second direction is different from a length of the second display area in the second direction.

15. A display device comprising:
a substrate including:
a display area; and
a peripheral area surrounding the display area and including a first peripheral area extending in a first direction and a second peripheral area extending in a second direction intersecting the first direction, wherein a second length of the second peripheral area in the second direction is longer than a first length of the first peripheral area in the first direction;
data lines disposed in the display area on the substrate and extending in the first direction;
main gate lines disposed in the display area on the substrate and extending in the second direction;
sub gate lines disposed in the display area on the substrate and extending in the first direction;
a data driver corresponding to the data lines and disposed in the second peripheral area on the substrate;
a main gate driver corresponding to the main gate lines and disposed in the first peripheral area on the substrate; and
a sub gate driver corresponding to the sub gate lines and disposed in the second peripheral area on the substrate.

16. The display device of claim 15, wherein a quantity of the main gate lines is equal to a quantity of the sub gate lines.

17. The display device of claim 15, wherein the main gate lines respectively correspond to the sub gate lines and are electrically connected to the sub gate lines.

18. The display device of claim 15, wherein a line connecting a center point of the sub gate driver and a center point of the display area is parallel to the first direction on a plane.

19. The display device of claim 15, wherein a length of the sub gate driver in the second direction is equal to a length of the main gate driver in the first direction.

20. The display device of claim 15, wherein:
the sub gate driver is disposed such that the sub gate driver is spaced apart from the data driver in the first direction on a plane; and
the display area is interposed between the sub gate driver and the data driver.
